(19) United States
(12) Patent Application Publication
(10) Pub. No.: US 2017/0145563 A1
(43) Pub. Date: May 25, 2017

(54) DIAMOND-COATED MACHINING TOOL AND METHOD FOR PRODUCTION THEREOF

(71) Applicant: Guhring KG, Albstadt (DE)

(72) Inventors: Stefan SATTEL, Strassberg (DE); lmmo GARRN, Ertingen (DE); Manfred SCHWENCK, Albstadt (DE)

(73) Assignee: Guhring KG, Albstadt (DE)

(21) Appl. No.: 15/367,688

(22) Filed: Dec. 2, 2016

Related U.S. Application Data
(63) Continuation of application No. PCT/EP2015/062266, filed on Jun. 2, 2015.

(30) Foreign Application Priority Data
Jun. 2, 2014 (DE) 10 2014 210 371.1

(51) Int. Cl. C23C 16/27; B24D 18/00; B23B 27/14; C23C 16/02

(52) U.S. Cl. CPC C23C 16/27; C23C 16/0263; B24D 18/00; B23B 27/148; B23B 2226/31; B23B 2228/04; B23B 2228/105

(57) ABSTRACT

A machining tool comprising at least one diamond-coated functional region having a substrate surface composed of a hard metal or a ceramic material arranged beneath the diamond layer. The substrate surface contains hard material particles on the basis of carbide and/or nitride and/or oxide, which are embedded in a cobalt-containing binding matrix. The diamond layer is directly arranged on the substrate surface without cobalt having been removed by chemical or physical methods in substantial amounts out of the binding matrix of the substrate surface. Such a tool is produced by pre-treating a hard metal substrate surface with a positively charged ion beam, followed by conventional CVD-diamond coating directly onto the ion beam-pre-treated cobalt-containing substrate surface. The ion-underlying atoms thereby largely remain in the substrate. The tools according to the invention have good diamond layer bonding to the substrate and a high wear resistance.

The present invention relates to a machining tool according to the preamble of claim 1, a method of producing a diamond coating on a functional region of a machining tool according to the preamble of claim 11 and also a machining tool according to claim 17.

Tools for machining having a tool head, a tool shaft and a clamping section for being received in a tool holder are known in the most varied forms from the prior art.

Tools of this kind have functional regions in their cutting part region which are adapted to the specific needs of the materials being machined.

The aforementioned tools are, in particular, those which are designed as drilling, milling, countersinking, turning, tapping, contouring or reaming tools which may exhibit cutting bodies or guide rails as the functional region, wherein the cutting bodies may be configured as interchangeable or reversible cutting plates, for example, and the guide rails may be configured as support bars, for example.

Typically, tool heads of this kind exhibit functional regions which give the tool a high degree of wear resistance during the machining of highly abrasive materials.

DE 20 2005 021 817 U1 which was filed by the present applicant describes tool heads which are made of a hard material having at least one functional layer which comprises an ultra-hard material such as cubic boron nitride (CBN) or polycrystalline diamond (PKD).

A tool of this kind enables long tool lives to be achieved by the tools in respect of the mechanical or thermal requirement for drilling, milling or reaming.

Methods of applying a polycrystalline film, in particular this kind of film made of diamond material, to non-diamond substrates have likewise been known in the art for some time. Hence, U.S. Pat. No. 5,082,359, for example, describes the application of a polycrystalline diamond film by means of chemical vapour deposition (CVD).

In the method described in this document of the prior art, a series of discrete nucleation points is produced on the surface of the substrate to be coated, which typically exhibit the shape of craters.

These craters, which act as growth initiation sites for the diamond deposition that is to follow, may be produced according to U.S. Pat. No. 5,082,359 using a series of methods, for example by laser vaporization and chemical etching or plasma etching with a photoresist in a corresponding pattern or also by means of focused ion beam milling.

U.S. Pat. No. 5,082,359 discloses that by means of a focused ion beam of Ga⁺ with a kinetic energy of 25 KeV in the substrates, by focussing the Ga⁺ ion beam to a diameter of less than 0.1 μm, craters can be produced at an interval of less than 1 μm.

U.S. Pat. No. 5,082,359 cites as substrates materials typically used in the semiconductor industry, such as germanium, silicon, gallium arsenide and also polished wafers of monocrystalline silicon and titanium, molybdenum, nickel, copper, tungsten, tantalum, steel, ceramic, silicon carbide, silicon nitride, silicon aluminium oxynitride, boron nitride, alumina, zinc sulphide, zinc selenide, tungsten carbide, graphite, fused silica, glass and sapphire are specified as further useful substrates.

Hard metals and, in particular, materials which are embedded in a cobalt-containing binding matrix are not mentioned.

Ultimately, the CVD is carried out through the reaction of methane and hydrogen in a vacuum on a hot tungsten wire, in order to deposit the carbon produced in the high vacuum on the crater-shaped irregularities produced in the substrate surface in its diamond modification.

In addition, it is known in the art for tools to be provided with functional surfaces with a diamond layer, wherein a CVD method is likewise used.

A diamond coating method of this kind is described in WO 98/35071 A1, for example. In particular, the deposition of a polycrystalline diamond film on a hard metal substrate of tungsten carbide embedded in a cobalt matrix is described in WO 2004/031437 A1.

For hard metal substrates or cermet, chemical or electrochemical etching was necessary according to WO 2004/031437 A1, in order to achieve good adhesion of the diamond coating produced on the substrate by means of CVD.

Typically, a hard metal contains sintered materials made of hard material particles and binding material, for example tungsten carbide grains, wherein the tungsten carbide grains form the hard materials and the cobalt-containing binding matrix serves as a binding agent for the WC grains and gives the layer the toughness necessary for the tool.

Diamond-coated hard metal or cermet tools have a naturally positive effect on wear protection of the tool and also on the life of said tool during continuous use.

However, good adhesion of the diamond coating to a hard metal substrate of this kind is always problematic, which is why different pretreatment methods are needed in the prior art which are all aimed at removing cobalt from the binding matrix for hard material particles, e.g. WC, because tests have shown that cobalt can affect deposition through different influences.

Hence, for example, U.S. Pat. No. 6,096,377 A1 describes a method of coating a hard metal substrate with a diamond layer, wherein the method comprises pretreatment of the substrate using a WC-selective etching step and also a cobalt-selective etching step. The application of the diamond layer involves seeding with diamond powder and subsequent CVD diamond coating, wherein the cobalt-selective etching step, the WC-selective etching step or seeding step can be performed in any order.

Moreover, DE 195 22 371 A1 on the application of a diamond layer to a hard metal substrate initially describes a cobalt-selective etching step with subsequent cleaning of the etched substrate surface and subsequently a WC-selective etching strep with subsequent cleaning. A diamond layer is then applied to the hard metal substrate pretreated in this manner by means of a CVD method.

According to WO 2004/031437 A1, two-stage pretreatment processes of this kind with an initial cobalt-selective etching step and a subsequent WC-selective etching step in many cases do not lead to an adequate layer adhesion of the diamond coating.

This may be due to the fact that when complete etching of the WC hard material particles lying on the surface takes place in the second WC-selective etching step, the surface subsequently includes a cobalt enrichment which prevents good adhesion of the diamond layer. If, on the other hand, the WC etching is only carried out partially, then the WC particles are etched at the grain limits on the surface, i.e. in the later transitional region between substrate and diamond layer, which is why there is no longer an intact WC, which leads to reduced diamond coating adhesion and reduced mechanical strength.

Moreover, WO 97/07264 describes a pretreatment method of a hard metal for CVD diamond coating, wherein electrochemical etching of the hard metal is carried out in a first step, in that the substrate is used as the anode in an electrolyte, for example 10% NaOH, and in this way is electrochemically etched. In a second step, the cobalt binding material is selectively etched. Following this, the diamond layer is applied by means of the CVD method.

It emerged in practice that the diamond coating was not capable of withstanding intense stresses, particularly shear stresses and dynamic compression stresses, such as those which occur in functional regions of machining tools. The adhesion of the CVD diamond coating achieved using this kind of electrochemical pretreatment on its substrate is obviously not sufficient, which means that the polycrystalline diamond coating becomes detached from the substrate during continuous use.

Unlike the alkaline etching method described above, the teaching in WO 2004/031437 A1 focuses on a first chemical etching step in the acid range which etches the binding material, in particular cobalt. According to WO 2004/031347 A1, electrochemical etching methods are used with direct or alternating current with HCl or H₂SO₄, but HNO₃ or mixtures of H₂SO₄/H₂O₂, HCl/H₂O₂ and HCl/HNO₃ can be used in addition for etching.

In a second etching step, the hard material particles, in particular tungsten carbide grains, are then etched. Chemicals known per se which etch WC selectively are used for this. Examples of this are treatment with potassium hexacyanoferrate (III)/alkaline solutions, KMnO₄/alkaline mixtures and also electrochemical methods with NaOH, KOH or Na₂CO₃ are disclosed.

In addition to the two steps, a further cobalt-selective etching step is performed, which is preferably carried out as electrochemical etching with sulphuric acid or hydrochloric acid. According to the teaching in WO 2004/031437 A1, a porous zone is produced on the surface of the substrate already profiled by the first two steps during this, in which the binding material is removed. The actual diamond coating likewise takes place by means of a CVD method. In this case, the diamond grows on the surface produced and, due to the depth profile of the pretreated substrate, excellent clamping should be created for the diamond coating in the substrate,

Moreover, DE 10 2006 026 253 A1 likewise discloses coated bodies and methods for the production thereof, wherein the body has a substrate made from a hard metal or cermet, comprising hard material particles and binder material and an adhering diamond coating attached thereto.

According to the teaching in DE 10 2006 026 253 A1, the substrate predominantly comprises WC and cobalt, wherein at least some of the hard material particles exhibit trans-crystalline depressions below the diamond coating in the form of holes.

This hole corrosion is achieved by means of trans-crystalline etching by chemical means, such that depressions in the form of indentations or holes occur within the WC grains.

According to the teaching in DE 10 2006 253 A1, following mechanical pretreatment, for example micro-radiation with hard material particles, acid etching is performed in the radiated functional region in concentrated sulphuric acid. In this case, the tool acts as the anode and, for example, the outer high-grade steel container as the cathode.

On account of this electrochemical treatment, a passivation layer forms which is closed to such an extent after 10 seconds that virtually no further etching can take place. Following this etching step, the passivation layer created is removed again using 10% NaOH and the cycle of electrochemical etching in acid with subsequent removal of the passivation layer in the alkaline medium is typically repeated many times.

This treatment means that the cobalt phase according to the teaching found there is completely removed close to the surface, while the tungsten carbide particles exhibit hole corrosion which should provide the following diamond coating by means of a CVD process with sufficient adhesion.

The method according to this state of the art should be adjusted in this case so that the cobalt loss is greater than the WC loss in the case of WC—Co hard metal.

DE 10 2006 026 253 A1 states that the substrate binder, in particular cobalt, is removed from the surface because during the long process time and high temperatures involved in the CVD diamond coating, harmful interactions occur between the carbon which is to form the diamond coating and the cobalt, wherein cobalt prevents the diamond formation and, instead of this, leads to graphite phases.

This effect of the cobalt-containing binding agent layer on the CVD diamond coating is also described in the most recent literature, for example in the review article by HAUBNER, R. and KALSS, W. (2010): Int. Journal of Refractory Metals and Hard Materials 28, 475-483: “Diamond deposition on hard metal substrates—Comparison of substrate pre-treatments and industrial applications”.

According to the comments made by HAUBNER et al., carbon can diffuse out of the CVD diamond coating into the cobalt-containing binding matrix, wherein at the same time cobalt droplets form during the diamond deposition from the gas phase which significantly affect the substrate structure and, as a result of this, a certain brittleness occurs. Moreover, according to HAUBNER et al. it was found that cobalt is a catalyst for diamond growth and the more or less spontaneous transformation thereof into graphite.

It is therefore understandable that for empirical reasons attempts were made in the prior art to remove cobalt from the binding matrix, in order to reduce the influence of cobalt on the diamond deposition.

However, all prior-art methods have one feature in common, in that although a removal of cobalt from the binding matrix leads to relatively good adhesion of the CVD diamond coating, the cobalt-depleted binding matrix for the hard material particles, in particular WC, is seriously affected and there is no longer any embedding of the WC grains as hard material particles as a result. This means that the integrity and mechanical strength of the substrate surface, in particular under the severe stresses to which it is exposed as a tool, can no longer be guaranteed. There are therefore structural disturbances in the substrate/diamond interphase, so that ultimately the diamond coating with parts of the substrate structure can be detached, rendering tools coated in this way unusable.

For this reason, tests were also carried out in the prior art aimed at providing a barrier layer in the form of thin films between the diamond coating and substrate surface, in order to undermine the disruptive influence of the cobalt on the diamond deposition and stability.

Methods of this kind, for example with copper, titanium or chromium sputtered or chemically deposited onto the substrate surface, are likewise described in HAUBNER et al.

However, it has emerged here, too, that intermediate layers of this kind are not necessarily optimal for adhesion of the CVD diamond coating deposited thereon, quite apart from their costly production and the quasi-continuous layer thickness monitoring required.

Since a cobalt-containing binding matrix has for some time proved successful in the prior art in the case of hard metal tools for the embedding of hard material particles, the problem addressed by the invention is therefore that of providing machining tools and also a method for the production thereof, in which a coating can be disposed directly on the substrate surface in stable diamond modification, i.e. without noticeable conversion of nascent and already crystallized diamond in graphite and without disturbing the structure of the binding matrix through cobalt depletion.

The problem is solved by the characterizing features of patent claims 1 and 17.

From a process point of view, the above problem is solved by the characterizing features of claim 11.

In particular, the present invention relates to a machining tool having at least one diamond-coated functional region with a substrate surface made of a hard metal or a ceramic material lying under the diamond layer, wherein the substrate surface contains hard material particles on a carbide and/or nitride and/or oxide basis which are embedded into a cobalt-containing binding matrix, wherein the diamond coating is arranged directly on the substrate surface, without cobalt having been removed in substantial quantities from the binding matrix of the substrate surface by means of chemical or physical methods.

The present invention further relates to a method of producing a diamond coating on a functional region of a machining tool, wherein the diamond coating is applied to a substrate surface made of a hard metal or a ceramic material, wherein the substrate surface contains hard material particles on a carbide and/or nitride and/or oxide basis which are embedded into a cobalt-containing binding matrix, wherein the substrate surface is pretreated using a positively charged ion beam of at least one ion species, wherein the atoms underlying the ion species substantially remain in the substrate and the diamond coating is applied by means of chemical vapour deposition (CVD) directly onto the ion beam-pretreated cobalt-containing substrate surface.

The pretreatment of the substrate surface of a functional region of a tool which contains hard material particles, e.g. WC grains, which are embedded in a cobalt-containing binding matrix, by means of ion beams, e.g. N⁺, N⁺⁺ and/or C⁺ means that substantially no cobalt is removed from the binding matrix, but the radiated ions are incorporated into the structure of the binding matrix.

Without being bound to it, cobalt could, for example, be converted by the radiated light ions into cobalt nitrides or cobalt carbon nitrides or also cobalt carbides which do not exhibit the catalytic action for conversion of the cubic diamond phase into the hexagonal graphite phase, so that the cubic diamond crystals have sufficient time to grow on the substrate surface, without an in-situ reconversion into graphite taking place.

Diamond-coated functional regions of this kind which can be produced using the method according to the invention have, surprisingly, proved substantially more stable in the long term in the case of machining tools than diamond layers which have been applied to cobalt-depleted substrate surfaces by means of CVD. In the practical test, improved layer adhesion of the diamond coating compared with the standard process of the prior art could be achieved.

This is even more surprising, since the teaching according to the invention practically suggests the opposite of the measures propagated in the prior art, namely instead of the conservative teaching of depleting the binding matrix of cobalt, it is essential for the present invention to retain practically the entire Co content in the binding matrix and to change the structure by means of an ion beam in such a manner that the Co atoms no longer affect the diamond deposition during a CVD process.

Although in the prior art in U.S. Pat. No. 5,082,359 ion beams were already used in the form of a focused ion beam of Ga⁺ for substrate treatment prior to CVD diamond deposition, only heavy Ga⁺ cations were used in that case which—following collision with the Co atoms of the binding matrix—force the Co atoms out of the metal lattice of the binding matrix, so that the binding matrix is heavily cobalt-depleted. Hence the use of heavy Ga⁺ ion beams can be introduced seamlessly into the cobalt depletion teaching and only represents an alternative to the prior-art chemical etching method described above and therefore a massive removal of Co atoms from the binding matrix.

Unlike the use of ion beams with heavy ion species in the prior art, the cobalt remains during radiation of the substrate surface according to the invention with the substantially lighter ion species N⁺, N⁺⁺ and/or C⁺ substantially in the binding matrix and consequently leads to substantially better adhering diamond coatings than in the prior art. Moreover, the embedding of the hard material particles, such as WC in the binding matrix, for example, and therefore the integrity of the hard material particle cobalt phase is practically unaffected, as a result of which it retains its advantageous properties for machining tools and does not become brittle, for example.

A preferred embodiment of the present invention is a machining tool with at least one diamond-coated functional region, in which the diamond coating of the functional region can be obtained according to the method in the invention.

The machining tools according to the invention can be used for all purposes in which the use of an at least partially diamond-coated tool is technical feasible, in order to machine either particularly abrasive materials—e.g. CFK materials—or to achieve long tool lives in the production of machine components, or both. In particular, the tools may be configured as a rotating or stationary tool, in particular as a drilling, milling, countersinking, turning, tapping, contouring or reaming tool.

The tools may be tools of monolithic or modular design.

An advantageous tool is one in which at least one cutting body, in particular a cutting plate, preferably an interchangeable or reversible plate, is provided on a carrier body and/or at least one guide rail, in particular a supporting strip, is provided, wherein the cutting body or the guide rails is diamond-coated at least in a partial region.

The tools in the present invention contain hard material particles which are chosen from the group comprising: carbides, carbon nitrides and nitrides of the metals in subgroup IV, V and VI of the periodic table of the elements and boron nitride, in particular cubic boron nitride; as well as oxidic hard materials, in particular aluminium oxide and chromium oxide; and also in particular titanium carbide, titanium nitride, titanium carbonitride, vanadium carbide, niobum carbide, tantal carbide, chromium carbide, molybdenum carbide, tungsten carbide and also mixtures and mixed phases thereof.

The binding matrix for the hard material particles may additionally contain, apart from cobalt, aluminium, molybdenum and/or nickel.

A preferred tool with functional regions or monoliths made of ceramic material is one in which the ceramic material is a sintered material made of the aforementioned hard material particles in a binding matrix which, apart from cobalt, additionally contains aluminium, chromium, molybdenum and/or nickel.

As a ceramic material, an advantageous tool is a sintered carbide or carbon nitride hard metal.

Typically, the diamond coating of the machining tools is polycrystalline and is applied by means of chemical vapour deposition (CVD).

CVD diamond deposition methods of this kind have probably been known to the person skilled in the art since 1982 (cf. MATSUMOTO, S, SATO, Y, KAMO M, & SETAKA, N (1982): Jpn J Appl Phys; 21 (4), L183-185: Vapor deposition of diamond particles from methane). In relation to the diamond coating of hard metal substrates by means of CVD methods, reference is made, for example, to the aforementioned review article by HAUBNER et al.

Typical layer thicknesses for the diamond coating on the tool surfaces lie in the range of 3 to 15 μm, in particular of 6 to 12 μm.

The ion beam used for the method according to the invention is produced by means of a standard ion beam generator, wherein the following ion species can be used: lithium, boron, carbon, silicon, nitrogen, phosphorous and/or oxygen, wherein nitrogen, in particular N⁺ and N⁺⁺ and/or carbon, in particular C⁺, are preferred.

Experiments have revealed that an ion beam with a kinetic energy of 3.2×10⁻¹⁵ J to 3.2×10⁻¹⁴ J [20 KeV to 200 KeV] is optimal for the deactivation of the catalytic effect of the cobalt in the binding matrix (in particular, inhibition of the conversion from diamond to graphite).

If the pretreatment of the substrate surface is carried out by means of ion beams in the vacuum between 20° C. and 450° C., in particular between 300° C. and 450° C., outstanding diamond adhesions to the substrate surface can be achieved.

Methane is used as the carbon source for the CVD diamond coating, wherein hydrogen is mixed into the methane in the molar surplus.

A particularly advantageous growth behaviour and adhesion of the diamond layer and also crystal size of the individual diamond crystals during the CVD deposition from methane/H₂ can be achieved if, following the ion beam pretreatment of the substrate surface, diamond nano-crystals are applied by means of ultrasound to the substrate surface for seeding for the following CVD diamond coating.

In this way, particularly stable diamond layers are produced and the hard metal or cermet tools coated in this manner exhibit long tool lives during the series production of components machined with them.

Further advantages and features result based on the description of a specific exemplary embodiment.

### EXAMPLE

Hard metal tools made of 10M % Co hard metal with an average WC grain size of 0.6 μm (Gühring trade name DK460UF) were radiated for 3.5 hrs according to the invention using an ion current of nitrogen ions, wherein the ion current was produced with a voltage of 30 kV with 3 mA plasma current at a nitrogen pressure of 1×10⁻⁵ mbar. A standard ion generator was used to produce the ion beam (“Hardion” iron generator from Quertech, Caen).

In this case, there is a temperature of approx. 400° C. on the tool. Following this, the tool was coated with diamond in a standard hot wire CVD unit (CemeCon CC800/5). An adhesive diamond layer 12 μm thick grew in a coating time of 60 hrs.

The coating adhesion was tested using the conventional radiation wear test according to a CemeCon standard. This radiation wear test involves the layer being blasted using a corundum jet with an average grain size of approx. 13 μm until the diamond layer being tested either blistered or is penetrated. If, after a blasting time of 2 minutes, no damage has occurred to the layer, the sample is classed as fatigue-tested without rupture. Good layer adhesion is assumed if the blasting time to failure is >30 secs. Of the tools treated according to the invention, 80% were fatigue-tested without rupture and no single result had a blasting time of under 110 secs, while the average life of conventionally prepared specimen tools was around 95 secs.

1. A machining tool having at least one diamond-coated functional region with a substrate surface made of a hard metal or a ceramic material lying under the diamond layer, wherein the substrate surface contains hard material particles on a carbide and/or nitride and/or oxide basis which are embedded into a cobalt-containing binding matrix,
and wherein the diamond coating is arranged directly on the substrate surface, without cobalt having been removed in substantial quantities from the binding matrix of the substrate surface by chemical or physical methods.

2. The tool according to claim 1, wherein the tool is configured as a rotating or stationary tool.

3. The tool according to claim 1, wherein the tool is monolithic.

4. The tool according to claim 1, wherein at least one cutting body is provided on a carrier body and/or at least one guide rail is provided, wherein the cutting body or the guide rails is diamond-coated at least in a partial region.

5. The tool according to claim 1, wherein the hard material particles are chosen from the group consisting of carbides, carbon nitrides and nitrides of the metals in subgroup IV, V and VI of the periodic table of the elements and boron nitride, as well as oxidic hard materials including aluminum oxide and chromium oxide, titanium carbide, titanium nitride, titanium carbon nitride, vanadium carbide, niobum carbide, tantalum carbide, chromium carbide, molybdenum carbide, tungsten carbide and also mixtures and mixed phases thereof.

6. The tool according to claim 1, wherein the binding matrix comprises, apart from cobalt, aluminum, chromium, molybdenum and/or nickel.

7. The tool according to claim 1, wherein the ceramic material is a sintered material made of hard material particles selected from the group consisting of carbides, carbon nitrides and nitrides of the metals in subgroup IV, V and VI of the periodic table of the elements and boron nitride, as well as oxidic hard materials including aluminum oxide and chromium oxide, titanium carbide, titanium nitride, titanium carbon nitride, vanadium carbide, niobum carbide, tantalum carbide, chromium carbide, molybdenum carbide, tungsten carbide and also mixtures and mixed phases thereof, in a binding matrix that further comprises, apart from cobalt, aluminum, chromium, molybdenum and/or nickel.

8. The tool according to claim 7, wherein the ceramic material is a sintered carbide or carbon nitride hard metal.

9. The tool according to claim 1, wherein the diamond coating is polycrystalline and is applied by means of chemical vapor deposition (CVD).

10. The tool according to claim 1, wherein the diamond coating has a thickness of between 3 and 15 μm.

11. A method of producing a diamond coating on a functional region of a machining tool, wherein the diamond coating is applied to a substrate surface made of a hard metal or a ceramic material, wherein the substrate surface contains hard material particles on a carbide and/or nitride and/or oxide basis which are embedded into a cobalt-containing binding matrix,
and wherein the substrate surface is pretreated using a positively charged ion beam of at least one ion species, wherein the atoms underlying the ion species substantially remain in the substrate and the diamond coating is applied by means of chemical vapor deposition (CVD) directly onto the ion beam-pretreated cobalt-containing substrate surface.

12. The method according to claim 11, wherein the ion species comprises at least one of lithium, boron, carbon, silicon, nitrogen, phosphorous and oxygen.

13. The method according to claim 12, wherein an ion beam with a kinetic energy of 3.2×10⁻¹⁵ J to 3.2×10⁻¹⁴ J [20 KeV to 200 KeV] is used.

14. The method according to claim 11, wherein the pretreatment of the substrate surface is carried out by means of ion beams in the vacuum between 20° C. and 450° C.

15. The method according to claim 11, wherein the carbon source for the CVD diamond coating is methane, wherein hydrogen is mixed into the methane in the molar surplus.

16. The tool according to claim 15, wherein following the ion beam pretreatment of the substrate surface, diamond nano-crystals are applied by means of ultrasound to the substrate surface for seeding for the following CVD diamond coating.

17. A machining tool having at least one diamond-coated functional region, wherein the diamond coating of the functional region following the method according to claim 11 can be obtained.

18. The tool according to claim 17, wherein the tool is configured as a rotating or stationary tool.

19. The tool according to claim 17, wherein the tool is monolithic.

20. The tool according to claim 18, wherein at least one cutting body is provided on a carrier body and/or at least one guide rail is provided, wherein the cutting body or the guide rails is diamond-coated at least in a partial region.

21. The tool according to claim 17, wherein the diamond coating is applied to a substrate surface made of a hard metal or a ceramic material, wherein the substrate surface contains hard material particles on a carbide and/or nitride and/or oxide basis which are embedded into a cobalt-containing binding matrix.

22. The tool according to claim 17, wherein the hard material particles are chosen from the group consisting of carbides, carbon nitrides and nitrides of the metals in subgroup IV, V and VI of the periodic table of the elements and boron nitride, as well as aluminum oxide and, chromium oxide, titanium carbide, titanium nitride, titanium carbon nitride, vanadium carbide, niobum carbide, tantalum carbide, chromium carbide, molybdenum carbide, tungsten carbide and also mixtures and mixed phases thereof.

23. The tool according to claim 17, wherein the binding matrix further comprises, apart from cobalt, aluminum, chromium, molybdenum and/or nickel.

24. The tool according to claim 17, wherein the ceramic material is a sintered material made of hard material particles selected from the group consisting of carbides, carbon nitrides and nitrides of the metals in subgroup IV, V and VI of the periodic table of the elements and boron nitride, as well as aluminum oxide, chromium oxide, titanium carbide, titanium nitride, titanium carbon nitride, vanadium carbide, niobum carbide, tantalum carbide, chromium carbide, molybdenum carbide, tungsten carbide and also mixtures and mixed phases thereof, in a binding matrix that further comprises, apart from cobalt, aluminum, chromium, molybdenum and/or nickel.

25. The tool according to claim 24, wherein the ceramic material is a sintered carbide or carbon nitride hard metal.

26. The tool according to claim 17, wherein the diamond coating is polycrystalline and can be applied by means of chemical vapor deposition (CVD), wherein the diamond layer has a thickness of between 3 and 15 μm.
